(19) United States
(12) Patent Application Publication
(10) Pub. No.: US 2012/0069314 A1
(43) Pub. Date: Mar. 22, 2012

(54) IMAGING OPTICS AND PROJECTION EXPOSURE INSTALLATION FOR MICROLITHOGRAPHY WITH AN IMAGING OPTICS OF THIS TYPE

(75) Inventors: Johannes Zellner, Aalen (DE); Aurelian Dodoc, Heidenheim (DE); Marco Pretorius, Oberkochen (DE); Christoph Menke, Oberkochen (DE); Wilhelm Ulrich, Aalen (DE); Hans-Juergen Mann, Oberkochen (DE)

(73) Assignee: CARL ZEISS SMT GMBH, Oberkochen (DE)

(21) Appl. No.: 13/235,866

(22) Filed: Sep. 19, 2011

Related U.S. Application Data
(63) Continuation of application No. PCT/EP2010/054341, filed on Mar. 16, 2010.
(60) Provisional application No. 61/164,522, filed on Mar. 30, 2009.

(30) Foreign Application Priority Data
Mar. 30, 2009 (DE) 102009014953.8

(51) Int. Cl. G03F 7/20; G03B 27/70; G02B 17/06

(52) U.S. Cl. 355/67; 359/364; 355/77

(57) ABSTRACT

An imaging optics has a plurality of mirrors which image an object field in an object plane in an image field in an image plane. A pupil plane is arranged in the imaging beam path between the object field and the image field. A stop is arranged in the pupil plane. The pupil plane is tilted at an angle (α) with respect to the object plane, where α is greater than 0.1°. The imaging optics results allows for a manageable combination of small imaging errors, manageable production and good throughput.

### CROSS-REFERENCE TO RELATED APPLICATIONS

This application is a continuation of, and claims benefit under 35 USC 120 to, international application PCT/EP2010/054341, filed Mar. 16, 2010, which claims benefit under 35 USC 119 of German Patent Application Serial No. 10 2009 014 953.8, filed Mar. 30, 2009, and priority under 35 USC 119(e) to U.S. Ser. No. 61/164,522, filed Mar. 30, 2009. International application PCT/EP2010/054341 is hereby incorporated by reference in its entirety.

### FIELD

The disclosure relates to an imaging optics with a plurality of mirrors, which image an object field in an object plane in an image field in an image plane and which has, in a pupil plane arranged in the imaging beam path between the object plane and the image plane, a stop. Furthermore, the disclosure relates to a projection exposure installation with an imaging optics of this type, a method for producing a microstructured component with a projection exposure installation of this type and a microstructured or nanostructured component produced by this method.

### BACKGROUND

Imaging optics are known from U.S. Pat. No. 7,414,781 and WO 2007/020 004 A1.

### SUMMARY

The disclosure provides an imaging optics that exhibits a manageable combination of small imaging errors, manageable production and good throughput for the imaging light.

In one aspect, the disclosure provides an imaging optics with a plurality of mirrors, which image an object field in an object plane into an image field in an image plane. A pupil plane is arranged in the imaging beam path between the object field and the image field.

A stop is arranged in the pupil plane. The pupil plane is tilted relative to the object plane, in other words adopts an angle (α) with respect to the object plane, which is greater than 0.1°. The imaging optics has more than four mirrors.

It was recognised according to the disclosure that a pupil plane tilted with respect to the object plane provides the possibility of also arranging a stop in the pupil which is likewise tilted with respect to the object plane without loss of shading quality while also guiding the imaging beams past the tilted stop in such a way that (in particular on the mirrors adjacent to the tilted pupil plane in the imaging beam path of the imaging optics) small maximum angles of incidence can be realised in comparison to prior art systems. These maximum angles of incidence may be smaller than 35°, smaller than 30°, smaller than 25° and may, for example, be 22.2° and 18.9°. This makes it possible to use highly reflective coatings on the mirrors, which involve only a relatively small tolerance bandwidth with regard to the angle of incidence of the imaging light. This allows for providing an imaging optics with a high total throughput for the imaging light. This is, in particular, advantageous where throughput losses have to be avoided, for example when EUV (extreme ultraviolet) light is used as the imaging light. The angle between the tilted pupil plane and the object plane may be greater than 1°, greater than 10°, greater than 20°, greater than 30°, greater than 40°, greater than 45°, and, in particular be 47°. The imaging optics may have more than one pupil plane. In this case, at least one of these pupil planes is tilted according to the disclosure. The stop arranged in the tilted pupil plane may be an aperture stop for specifying an outer edge shape of a pupil of the imaging optics and/or an obscuration stop for the defined shading of an inner portion of the pupil. A pupil of an imaging optics is generally taken to mean all the images of the aperture stop, which delimit the imaging beam path. The planes, in which these images come to rest, are called pupil planes. As, however, the images of the aperture stop are not inevitably precisely planar, as a generalisation, the planes, which approximately correspond to these images are also called pupil planes. The plane of the aperture stop itself is also called a pupil plane. If the aperture stop is not planar, as in the images of the aperture stop, the plane, which best corresponds to the aperture stop, is called the pupil plane. The imaging optics has more than four mirrors. In comparison to imaging optics with at most four mirrors, this allows a greater degree of flexibility in the design of the imaging optics and also provides a higher number of degrees of freedom to minimise imaging errors. The imaging optics may have precisely six mirrors.

The entry pupil of the imaging optics is taken to mean the image of the aperture stop which is produced if the aperture stop is imaged by the part of the imaging optics, which is located between the object plane and aperture stop. Accordingly, the exit pupil is the image of the aperture stop which is produced if the aperture stop is imaged by the part of the imaging optics, which is located between the image plane and aperture stop.

If the entry pupil is a virtual image of the aperture stop, in other words the entry pupil plane is located in front of the object field, a negative back focus of the entry pupil is referred to. In this case, the chief rays or main beams run to all the object field points as if they came from a point in front of the imaging beam path. The chief ray to each object point is defined as the connecting beam between the object point and the centre point of the entry pupil. Where there is a negative back focus of the entry pupil, the chief rays to all the object points therefore have a divergent beam course on the object field.

An alternative definition of a pupil is that region in the imaging beam path of the imaging optics, in which individual beams issuing from the object field points intersect, which, relative to the chief rays issuing from these object field points, are in each case associated with the same illumination angle. The plane in which the intersection points of the individual beams are located according to the alternative pupil definition or which is closest to the spatial distribution of these intersection points, which does not inevitably have to be located precisely in a plane, can be called the pupil plane.

In some embodiments the image plane extends parallel to the object plane. Such embodiments can have a simplified structure for the overall installation having the imaging optics.

In some embodiments, the imaging beam path passes through a pupil in the pupil plane precisely once. Such embodiments can avoid vignetting problems. Problems of this type may occur, for example, if the tilted pupil plane is arranged directly at or on one of the mirrors, so both the imaging beams running onto this mirror and also the imaging beams reflected by this mirror are shaded by the stop, which corresponds to a double passage of the aperture stop. The single passing through of the pupil of the tilted pupil plane can be used for the pupil forming of imaging light.

In some embodiments, the pupil plane is tilted relative to a chief ray which belongs to a central object field point (in other words, the pupil plane has an angle (β) with respect to the chief ray, which belongs to the central object field point, that is smaller than 90°). Such a pupil plane of the imaging optics will also be called a tilted pupil plane below. The reference variable relative to which the pupil plane according to this second aspect is tilted, is the chief ray, which belongs to the central object field point, and is therefore a different reference variable than in the tilted pupil plane according to the previously described first aspect. Thus, with a tilted pupil plane according to the first aspect, the chief ray belonging to a central object field point can pass through the pupil plane along a normal. A tilted pupil plane according to the second aspect may in turn be arranged parallel to the object plane or to the image plane. The image plane may also extend parallel to the object plane in the imaging optics according to the second aspect. The angle between the pupil plane and the chief ray, which belongs to the central object field point, may be smaller than 85°, smaller than 80°, smaller than 75° and for example be about 70°. The stop is tilted in this configuration to the chief ray direction of the imaging beam path. This also simplifies a design with a small maximum angle of incidence, in particular on the mirrors adjacent to the tilted pupil plane. In the imaging optics according to the second aspect, more than one pupil stop may also be present. The stop may be an aperture stop and/or an obscuration stop. The stop arranged in the pupil plane according to the second aspect may be passed through precisely once, which can be used for pupil forming purposes for the imaging light.

In some embodiments, the imaging optics includes a first imaging part beam in front of a last mirror in front of the tilted pupil plane, a second imaging part beam after a first mirror after the tilted pupil plane, and the first and second imaging part beams pass opposing outer edges of the stop. Such embodiments can avoid vignetting problems in the guidance of the folded imaging beam path past the various mirrors and past the tilted pupil plane.

In some embodiments, the tilted pupil plane is between a second mirror and a third mirror in the imaging beam path after the object field. Such an arrangement of the tilted pupil plane can allow for a compact design of the imaging optics.

In some embodiments, a reflection surface of at least one of the mirrors is a static free form surface. The use of such a static free form surface can significantly increase the degrees of freedom in the guidance of the imaging light through the imaging optics. The free form surface may be configured as a static free form surface. A static free form surface is taken to mean a free form surface, which is not actively changed with respect to its shape during the projection use of the imaging optics. Of course, a static free form surface may also be displaced as a whole for adjusting purposes. The free form surface is designed proceeding from an aspherical reference surface, which can be described by a rotationally symmetrical function. The aspherical surface best adapted to the free form surface may coincide with the aspherical reference surface. The imaging optics may have precisely one free form surface of this type or else a plurality of free form surfaces of this type.

In some embodiments, the imaging optics is a projection optics for microlithography. In such embodiments, the projection optics can be particularly advantageous.

The advantages of an optical system according to the disclosure and a projection exposure installation according to the disclosure correspond to those which were listed above in relation to the imaging optics according to the disclosure. The light source of the projection exposure installation may be broad-band and, for example, have a bandwidth, which is greater than 1 nm, greater than 10 nm or greater than 100 nm. In addition, the projection exposure installation may be designed such that it can be operated with light sources of different wavelengths. Light sources for other wavelengths, in particularly used for microlithography, can also be used in conjunction with the imaging optics according to the disclosure, for example light sources with the wavelengths 365 nm, 248 nm, 193 nm, 157 nm, 126 nm, 109 nm and in particular also with wavelengths, which are less than 100 nm, for example between 5 nm and 30 nm.

The light source of the projection exposure installation can be configured to produce illumination light with a wavelength of between 5 nm and 30 nm. A light source of this type involves reflective coatings on the mirrors, which, in order to satisfy a minimum reflectivity, only have a small angle of incidence acceptance bandwidth. The desire for a small angle of incidence acceptance bandwidth can be satisfied together with the imaging optics according to the disclosure.

Corresponding advantages apply to a production method according to the disclosure and the microstructured or nanostructured component produced thereby.

### BRIEF DESCRIPTION OF THE DRAWINGS

Embodiments of the disclosure will be described in more detail below with the aid of the drawings, in which:

FIG. 1 schematically shows a projection exposure installation for EUV microlithography; and

FIG. 2 shows an imaging optics of the projection exposure installation, shown in meridional section.

### DETAILED DESCRIPTION

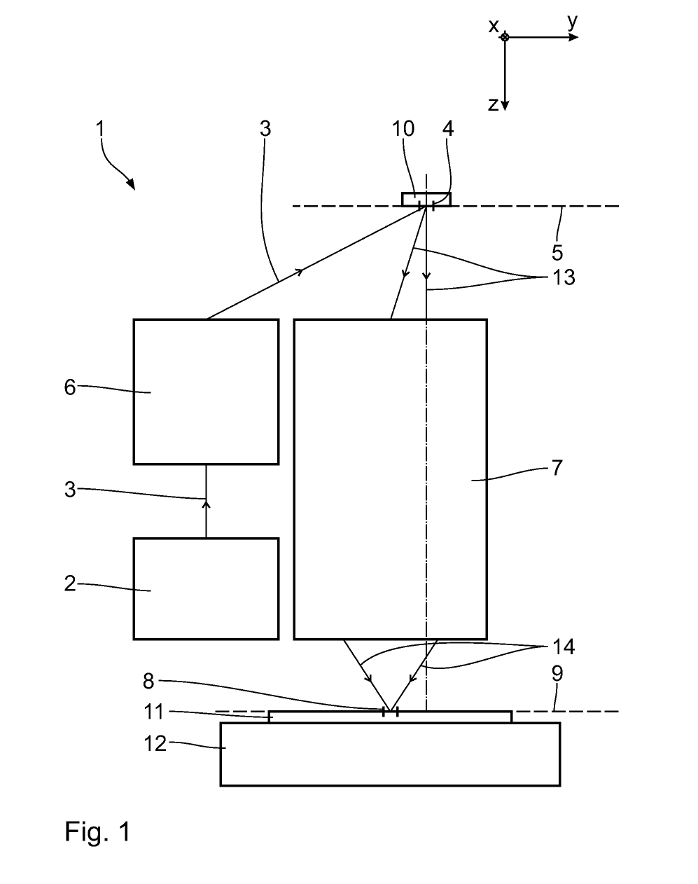

A projection exposure installation 1 for microlithography has a light source 2 for illumination light or illumination radiation 3. The light source 2 is an EUV light source, which produces light in a wavelength range, for example, between 5 nm and 30 nm, in particular between 5 nm and 15 nm. The light source 2 may, in particular, be a light source with a wavelength of 13.5 nm or a light source with a wavelength of 6.9 nm. Other EUV wavelengths are possible. In general, even any wavelengths, for example visible wavelengths or else other wavelengths, which may be used in microlithography and are available for suitable laser light sources and/or LED light sources (for example 365 nm, 248 nm, 193 nm, 157 nm, 129 nm, 109 nm) are possible for the illumination light 3 guided in the projection exposure installation 1. A beam path of the illumination light 3 is shown highly schematically in FIG. 1.

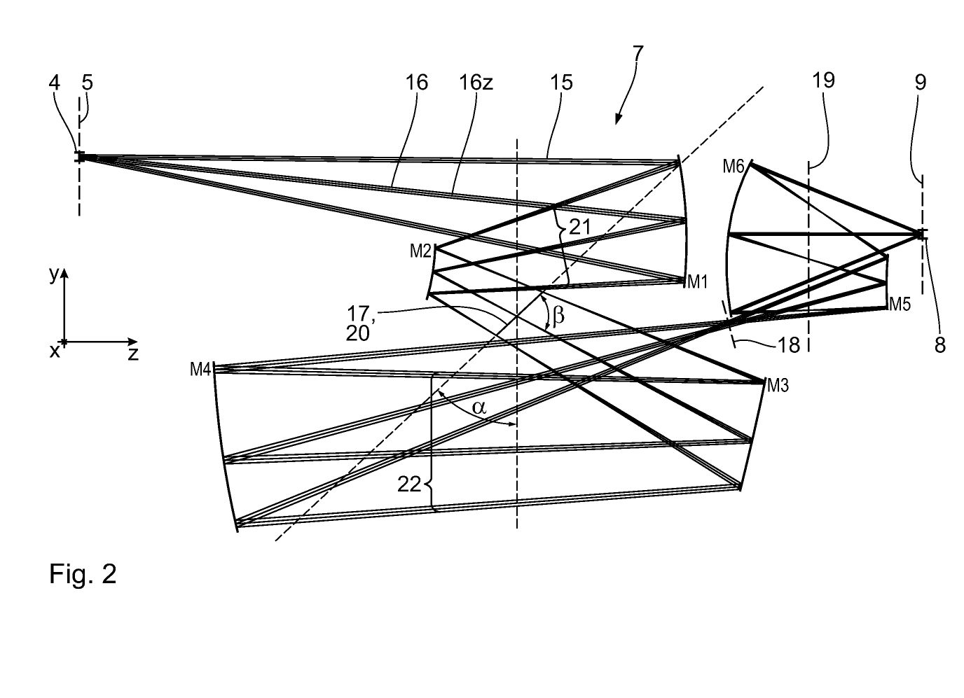

An illumination optics 6 is used to guide the illumination light 3 from the light source 2 toward an object field 4 in an object plane 5. Using projection optics or imaging optics 7, the object field 4 is imaged in an image field 8 in an image plane 9 at a predetermined reduction scale. The projection optics 7 according to FIG. 2 reduces by a factor of 4.

Other reduction scales are also possible, for example 5×, 6× or 8× or else reduction scales, which are greater than 8× or which are less than 4×, for example 2× or 1×. An imaging scale of 4× is particularly suitable for the illumination light 3 with an EUV wavelength, as this is a common scale for microlithography and allows a high throughput with a reasonable size of a reflection mask 10, which is also called a reticle and carries the imaging object. In addition, with an imaging of 4×, the desired structure size on the reflection mask 10 is adequately large to keep production and qualification outlay for the reflection mask 10 within limits. The image plane 9 in the projection optics 7 in the configurations according to FIG. 2ff, is arranged parallel to the object plane 5. A detail of the reflection mask 10 coinciding with the object field 4 is imaged here.

The imaging by the projection optics 7 takes place on the surface of a substrate 11 in the form of a wafer, which is carried by a substrate holder 12. FIG. 1 schematically shows, between the reticle 10 and the projection optics 7, a beam bundle 13 running therein of the illumination light 3 and, between the projection optics 7 and the substrate 11, a beam bundle 14 of the illumination light 3 issuing from the projection optics 7. The illumination light 3 imaged by the projection optics 7 is also called imaging light. A numerical aperture on the image field side, of the projection optics 7 in the configuration according to FIG. 2 is 0.38. This is not shown to scale in FIG. 1.

To facilitate the description of the projection exposure installation 1 and the projection optics 7, a Cartesian xyz-coordinate system is given in the drawing, from which the respective position relationship of the components shown in the Figs emerges. In FIG. 1, the x-direction runs perpendicular to the plane of the drawing and into it. The y-direction runs to the right and the z-direction downward.

The projection exposure installation 1 is of the scanner type. Both the reticle 10 and the substrate 11 are scanned during operation of the projection exposure installation 1 in the y-direction. A stepper type of projection exposure installation 1, in which a stepwise displacement of the reticle 10 and the substrate 11 takes place in the y-direction between individual exposures of the substrate 11, is also possible.

FIG. 2 shows the optical design of the projection optics 7. The beam path is shown of three respective individual beams 15, which issue from three object field points which are spaced apart from one another in the y-direction in FIG. 2. The three individual beams 15, which belong to one of these three object field points, are in each case associated with three different illumination directions for the three object field points. Chief rays or main beams 16 run through the centre of pupils in pupil planes 17, 18 of the projection optics 7. These chief rays 16 firstly run divergently, proceeding from the object plane 5. This will also be called a negative back focus of an entry pupil of the projection optics 7 below. The entry pupil in the projection optics 7 is not located in the beam path between the object field 4 and the image field 8, but in the imaging beam path in front of the object field 4. This allows, for example, a pupil component of the illumination optics 6 in the entry pupil of the projection optics 7 to be arranged in the beam path in front of the projection optics 7, without further imaging optical components having to be present between this pupil component and the object plane 5.

The projection optics 7 according to FIG. 2 has a total of six mirrors, which are numbered M1 to M6 consecutively in the order of the imaging beam path of the individual beams 15, proceeding from the object field 4. Only the calculated reflection surfaces of the mirrors M1 to M6 are shown in FIG. 2. The mirrors M1 to M6 are generally larger than the actually used reflection surfaces.

The mirrors, M1, M4 and M6 are configured as concave mirrors. The mirrors M2 and M5 are configured as convex mirrors. The mirror M3 is configured virtually as a planar mirror but is no flat folding mirror.

The mirrors M1 and M6 are arranged back to back with regard to the orientation of their reflection surfaces.

A first pupil plane 17 located within the projection optics 7, in the projection optics 7 is located between the mirrors M2 and M3. An intermediate image plane 18 is located in the imaging beam path between the mirrors M4 and M5 directly next to the mirror M6. A further pupil plane is located in the imaging beam path between the mirrors M5 and M6.

The pupil plane 17 is a tilted pupil plane which is mechanically accessible for the arrangement of a stop. An aperture stop 20 for pupil forming of the illumination or imaging light 3 is arranged there. The pupil plane 17 adopts an angle α with respect to the object plane 5 or with respect to the image plane 9, which is 47.4°. The aperture stop 20 presets an outer edge shape of an exit pupil of the projection optics 7. Alternatively or additionally, an obscuration stop may also be arranged in the pupil plane 17 for the defined shading of an inner portion of the exit pupil.

The pupil plane 17 is passed through precisely once by the imaging light 3.

The pupil plane 17, with respect to a chief ray 16_{z}, which belongs to a central object field point in the meridional plane shown in FIG. 2, adopts an angle α, which is about 70°.

Because of the tilting of the pupil plane 17 about the angle α or β, a design of the projection optics 7 is made possible, in which small maximum angles of incidence of the imaging light 3 are made possible in particular on the two mirrors M2 and M3 adjacent to the pupil plane 17.

The maximum angle of incidence of the imaging light 3 on the mirror M2 is 22.2°.

The maximum angle of incidence of the imaging light 3 on the mirror M3 is 18.9°.

A first imaging part beam 21 in front of the mirror M2, in other words in front of the last mirror in front of the pupil plane 17, and a second imaging part beam 22 directly after the mirror M3, in other words directly after the first mirror after the pupil plane 17, pass opposing edges of the aperture stop 20.

The optical data of the projection optics 7 according to FIG. 2 will be shown below with the aid of a table divided into a plurality of sub-tables.

The precise shape of the individual reflection surfaces of the mirrors M1 to M6 is produced as the sum of a biconic term and a free form term in the form of an XY-polynomial according to the following formula:

$$z = \frac{{x}^{2} / R D X + {y}^{2} / R D Y}{1 + \sqrt{1 - ( 1 + C C X ) {x}^{2} / R D {X}^{2} - ( 1 + C C Y ) {y}^{2} / R D {Y}^{2}}} + {\sum }_{i = 0}^{n} {\sum }_{j = 0}^{n} {a}_{i , j} {x}^{i} {y}^{j}$$

x and y designate the coordinates here on the respective surface. The local coordinate systems are displaced here with respect to a global reference system in the y-coordinate direction (y-decentration) and tilted about the x-axis (x-tilting).

z designates the arrow height of the free form surface in the respective local face coordinate system. RDX and RDY are the radii of the free form surface in the xz- and in the yz-section, in other words the inverses of the respective surface curvatures in the coordinate origin. CCX and CCY are conical parameters. The polynomial coefficients given are the coefficients a_{i,j}.

The value “spacing” in the first of the following sub-tables designates the spacing from the respective following component.

Projection optics 7

| | Object | M1 | M2 | M3 | M4 | M5 | M6 |
|---|---|---|---|---|---|---|---|
| Spacing | 1330.69385 | −557.627303 | 708.243742 | −1142.85285 | 1430.866193 | −351.192399 | 430.425369 |
| y-decentration | | −189.153638 | −271.278827 | −593.835308 | −766.851306 | −277.066725 | −259.250977 |
| [mm] | | | | | | | |
| x-tilting [°] | | −0.068634 | 10.892544 | 12.747514 | −11.95434 | 0.995543 | −2.191898 |
| RDX [mm] | | −1070.871391 | 378.073494 | −1300.303855 | −1899.56342 | 199.567522 | −452.627131 |
| RDY [mm] | | −976.69765 | −690.047429 | −917.175204 | 7743.717633 | 202.531238 | −443.435387 |
| CCX | | 0 | 0 | 0 | 0 | 0 | 0 |
| CCY | | 0 | 0 | 0 | 0 | 0 | 0 |

| Polynomial coefficient | | | | | | | |
|---|---|---|---|---|---|---|---|
| X**i | y**j | M1 | M2 | M3 | M4 | M5 | M6 |
| 2 | 0 | 7.651793E−06 | −3.785153E−04 | 2.879773E−04 | −2.868417E−05 | −1.635862E−03 | 6.086975E−05 |
| 0 | 2 | 5.371476E−05 | 1.737947E−03 | 4.733410E−04 | −3.507888E−04 | −1.692949E−03 | 8.446692E−05 |
| 2 | 1 | 1.528780E−08 | 7.635459E−07 | −1.466654E−07 | −3.520507E−10 | 1.761890E−06 | −9.657166E−08 |
| 0 | 3 | −2.033494E−09 | 1.096626E−06 | −4.802219E−08 | −3.350169E−09 | 3.860919E−07 | −1.773111E−08 |
| 4 | 0 | 8.724018E−12 | −1.715400E−10 | −4.158718E−11 | −1.483351E−12 | −1.174518E−08 | 1.345443E−10 |
| 2 | 2 | 5.339897E−11 | 2.367333E−09 | 1.583325E−10 | −6.032420E−11 | −1.926549E−08 | 3.881972E−10 |
| 0 | 4 | 4.470798E−11 | 3.803124E−09 | 1.267599E−10 | −2.797153E−11 | −1.069009E−08 | 2.103339E−10 |
| 4 | 1 | 6.471511E−15 | 5.213579E−12 | −2.647019E−13 | 3.326177E−15 | 1.846376E−11 | −4.424293E−13 |
| 2 | 3 | −1.998756E−14 | 4.308265E−11 | −2.044010E−13 | 1.601139E−14 | 4.345954E−11 | −5.340721E−13 |
| 0 | 5 | 2.392437E−14 | −1.325441E−11 | 1.895192E−13 | 4.070884E−14 | −7.295815E−12 | −4.450410E−14 |
| 6 | 0 | 7.901848E−18 | −1.041209E−14 | −5.024097E−17 | 3.715636E−18 | −1.342384E−13 | 3.310262E−16 |
| 4 | 2 | 4.343412E−17 | 5.797301E−14 | −6.124526E−16 | −3.346679E−18 | −4.520468E−13 | 1.672236E−15 |
| 2 | 4 | 9.741217E−17 | −1.327696E−13 | 5.825645E−17 | −7.394452E−17 | −2.559015E−13 | 1.962740E−15 |
| 0 | 6 | −1.062718E−16 | 1.959294E−13 | 7.887476E−16 | −2.655830E−16 | −7.477396E−14 | 1.204820E−15 |
| 6 | 1 | −1.391817E−22 | 1.371466E−16 | −1.243631E−19 | 4.750035E−21 | 4.450177E−16 | −1.749391E−18 |
| 4 | 3 | −5.042526E−20 | 2.051000E−16 | −1.055869E−18 | −3.605139E−20 | 6.169208E−16 | −4.286471E−18 |
| 2 | 5 | −7.517225E−20 | 2.888296E−15 | −6.421060E−19 | 2.063961E−19 | 5.728123E−16 | −3.972902E−18 |
| 0 | 7 | 4.514499E−19 | −7.458838E−16 | −6.965850E−18 | 1.317042E−18 | −1.169984E−15 | −3.751270E−18 |
| 8 | 0 | −2.249703E−25 | 1.879685E−19 | 1.865490E−22 | 2.858313E−24 | −2.789321E−18 | 1.020537E−21 |
| 6 | 2 | 9.618696E−23 | −1.307586E−18 | −7.040576E−22 | 2.693660E−23 | −6.359395E−18 | 7.515349E−21 |
| 4 | 4 | 4.152614E−22 | 5.476085E−19 | −2.793697E−21 | 2.342709E−22 | −1.097113E−17 | 1.613314E−20 |
| 2 | 6 | 2.012692E−21 | −4.982682E−17 | −5.582448E−21 | −3.599690E−22 | −7.896961E−18 | 2.276418E−20 |
| 0 | 8 | −1.670620E−21 | 4.999865E−18 | −4.696409E−20 | −4.362010E−21 | −1.302749E−17 | 1.243271E−20 |
| 8 | 1 | 9.121520E−27 | −3.901016E−22 | 1.020670E−24 | −1.489633E−28 | 9.554198E−21 | −6.739667E−24 |
| 6 | 3 | 3.378031E−25 | −3.600711E−21 | −4.982307E−24 | −9.208653E−26 | 5.644310E−20 | −2.305324E−23 |
| 4 | 5 | −2.303521E−24 | 7.184598E−21 | −1.597483E−23 | −6.298048E−25 | 5.165746E−20 | −4.548523E−23 |
| 2 | 7 | −9.766881E−24 | 4.344373E−19 | −8.766463E−23 | 4.036785E−26 | 3.470226E−19 | −6.515923E−23 |
| 0 | 9 | 5.282909E−24 | −6.407964E−20 | 1.170643E−23 | 7.707831E−24 | 2.187385E−19 | −1.671689E−23 |
| 10 | 0 | 3.721162E−29 | −7.642119E−24 | −1.067762E−27 | 1.403956E−29 | −4.087293E−23 | 1.653756E−28 |
| 8 | 2 | −3.652356E−28 | 5.605620E−23 | 8.063235E−28 | 8.158023E−29 | −2.522082E−22 | −3.800397E−27 |
| 6 | 4 | −2.437748E−27 | 2.654084E−22 | −3.554079E−26 | 3.062915E−28 | −4.744488E−22 | 1.939290E−26 |
| 4 | 6 | 7.335216E−27 | 7.431988E−23 | −1.458571E−25 | 7.138636E−28 | −9.182602E−22 | 9.938038E−26 |
| 2 | 8 | 1.058829E−26 | −7.352344E−22 | −5.826656E−26 | 4.949294E−28 | −4.503482E−23 | 1.259617E−25 |
| 0 | 10 | −4.497373E−27 | 3.175801E−22 | 6.641212E−25 | −5.402030E−27 | −2.284624E−22 | 2.740074E−26 |

All the mirrors M1 to M6 are configured as free form surfaces in the projection optics 7.

The image field 8 of the projection optics 7 is rectangular and has an extent of 26 mm in the x-direction and an extent of 2 mm in the y-direction.

Typical characteristics of the projection optics 7 will be summarised again below.

| | Projection optics 7 |
|---|---|
| NA | 0.38 |
| Field size [mm²] | 26 × 2 |
| Field form | Rectangle |
| Ring field radius [mm] | no data |
| (only for ring fields) | |
| Spacing entry pupil-reticle [mm] | −1495 |
| Chief ray angle at the reticle [°] | −6 |
| Installation length [mm] | 1849 |
| Wavefront error rms [mλ] | 12.7 |
| Distortion [nm] | 0.87 |
| Telecentricity [mrad] | 0.62 |

NA designates the numerical aperture on the image side of the projection optics 7.

The installation length here designates the spacing between the object plane 5 and the image plane 9.

The imaging errors given in the above table, in other words the wavefront error, the distortion and the telecentricity are maximum values over the image field 8.

The telecentricity value given in the table is the angle of dense beam of an illumination light beam bundle issuing from a point of the object field 4 toward a surface normal of the image plane 9.

To produce a microstructured or nanostructured component, the projection exposure installation 1 is used as follows: firstly, the reflection mask 10 or the reticle and the substrate or the wafer 11 are provided. A structure on the reticle 10 is then projected onto a light-sensitive layer of the wafer 11 with the aid of the projection exposure installation 1. By developing the light-sensitive layer, a microstructure or a nanostructure is then produced on the wafer 11 and therefore the micro- or nanostructured component is produced.

What is claimed is:

1. An imaging optics, comprising:
a plurality of mirrors configured to image an object field in an object plane into an image field in an image plane along an imaging beam path; and
a stop arranged in a pupil plane,
wherein:
the pupil plane is in the imaging beam path between the object field and the image field;
the pupil plane is tilted at an angle greater than 0.1° relative to the object plane; and
the plurality of mirrors comprises more than four mirrors.

2. The imaging optics of claim 1, wherein the image plane extends parallel to the object plane.

3. The imaging optics of claim 1, wherein the imaging beam path passes through a pupil in the pupil plane precisely once.

4. The imaging optics of claim 1, wherein a chief ray belongs to a central object field point, the pupil plane is tilted relative to the chief ray, and an angle between the pupil plane and the chief ray is less than 90°.

5. The imaging optics of claim 1, wherein:
the imaging optics has a first imaging part beam in front of a last mirror in front of the stop along the imaging beam path;
the imaging optics has a second imaging part beam after a first mirror after the stop along the imaging beam path; and
the first and second imaging part beams pass opposing outer edges of the stop.

6. The imaging optics of claim 1, wherein plurality of mirrors comprises second and third mirrors along the imaging beam path after the object field, and the pupil plane is between the second and third mirrors.

7. The imaging optics of claim 1, wherein at least one of the plurality of mirrors has a reflection surface that is a static free form surface.

8. The imaging optics of claim 1, wherein at least one of the plurality of mirrors has a reflection surface that is a free form surface.

9. The imaging optics of claim 1, wherein the imaging optics is a microlithography projection optics.

10. The imaging optics of claim 9, wherein the plurality of mirrors includes precisely six mirrors.

11. The imaging optics of claim 1, wherein the plurality of mirrors includes precisely six mirrors.

12. A projection exposure apparatus, comprising:
a projection optics comprising the imaging optics of claim 1; and
an illumination optics configured to guide illumination light toward the object field of the imaging optics.

13. The projection exposure apparatus of claim 12, wherein the projection exposure apparatus is a microlithography projection exposure apparatus.

14. The projection exposure apparatus of claim 12, further comprising a light source configured to provide the illumination light.

15. The projection exposure apparatus of claim 14, wherein the illumination light has a wavelength of between 5 and 30 nm.

16. A method, comprising:
a) providing a projection exposure apparatus which comprises:
a projection optics comprising the imaging optics of claim 1; and
an illumination optics configured to guide illumination light toward the object field of the imaging optics; and
b) using the projection exposure apparatus to project a structure of a reticle onto a light-sensitive layer of a wafer.

17. The method of claim 16, further comprising, after b), producing a structure on the wafer.

18. An imaging optics, comprising:
a plurality of mirrors configured to image an object field in an object plane into an image field in an image plane along an imaging beam path, the plurality of mirrors including precisely six mirrors; and
a stop arranged in a pupil plane,
wherein:
the pupil plane is in the imaging beam path between the object field and the image field
the pupil plane is tilted relative to the object plane at an angle greater than 0.1°
the image plane extends parallel to the object plane;
the imaging beam path passes through a pupil in the pupil plane precisely once; and
the imaging optics is a microlithography projection optics.

19. The imaging optics of claim 18, wherein a chief ray belongs to a central object field point, the pupil plane is tilted relative to the chief ray, and an angle between the pupil plane and the chief ray is less than 90°.

20. The imaging optics of claim 18, wherein plurality of mirrors comprises second and third mirrors along the imaging beam path after the object field, and the pupil plane is between the second and third mirrors.
